(19) United States
(12) Patent Application Publication
(10) Pub. No.: US 2025/0240870 A1
(43) Pub. Date: Jul. 24, 2025

(54) POWER DELIVERY SYSTEM FOR HIGH DENSITY SIGNALING AND HIGH POWER DELIVERY APPLICATION

(71) Applicant: Cisco Technology, Inc., San Jose, CA (US)

(72) Inventors: Wenbin Ma, Shanghai (CN); Mingjian Gao, Shanghai (CN); Weiying Ding, Shanghai (CN); Mingtong Zuo, Shanghai (CN); Yuqing Zhu, Shanghai (CN); Mike Sapozhnikov, San Jose, CA (US); Shuo Zhang, Shanghai (CN); David Nozadze, San Jose, CA (US)

(21) Appl. No.: 18/591,426

(22) Filed: Feb. 29, 2024

Related U.S. Application Data
(60) Provisional application No. 63/624,334, filed on Jan. 24, 2024.

(51) Int. Cl. H05K 1/02; H05K 1/11; H05K 3/00; H05K 3/42; H05K 3/46

(52) U.S. Cl. CPC H05K 1/0207; H05K 1/115; H05K 3/0047; H05K 3/425; H05K 3/4652

(57) ABSTRACT

A design and process address power delivery problems for PTH and one-step HDI designs. In some implementations, the quantity of layers may be reduced and the thickness of the board may be reduced. In one embodiment, a PCB is back drilled and a round cap plating is performed to get a more uniform power plane. In one implementation, the back drilled section of a VIA is plated as well, which provides a much bigger shape that is plated for power delivery.

### CROSS-REFERENCE TO RELATED APPLICATION

This application claims priority to and the benefit of U.S. Provisional Application No. 63/624,334, filed Jan. 24, 2024, entitled “Power Delivery System for High Density Signaling and High Power Delivery Application”, the entire disclosure of which is incorporated herein by reference in its entirety for all purposes.

### TECHNICAL FIELD

The present disclosure relates to circuit boards and, more particularly, to circuit boards that have a structure that improves power delivery.

### BACKGROUND

For a high power and dense system, it is very challenging to design the system so that it has satisfactory signal integrity to achieve the best performance of insertion loss, reflections, and crosstalk. In addition, power integrity is very challenging because the power plane shape is shrunken and broken with more stitching VIAs to try to optimize crosstalk performance.

For a 224 Gbps high density application specific integrated circuit (ASIC), a 102.4 Tbps switch has 512 lanes of 224 Gbps SerDes and power consumption more than 1200 W. It is very challenging to develop a design for signal integrity and achieve the best performance of insertion loss, reflections, and crosstalk (XTALK) in a high power and dense system. In addition, power integrity is very challenging since the power plane shape is shrunken and/or broken with more stitching VIAs for optimized XTALK performance.

For a next generation 102.4 Tbps high density and high-power switch system, the front port (either QSFPDD1600 or OSFP1600) configuration would be 64×1.6 Tbps, achieved by a 2×1 Belly-to-Belly stacked cage. A 1.6 Tbps optics module worst case power consumption is approximately 45 W. It is very challenging to successfully deliver an ASIC (˜1200 W) and optics power. The power delivery, signal integrity and thermal control are essential for a next generation system.

A related art design uses one lamination structure and advanced PCB technology such as a high-density interconnect (HDI) process. For a 102.4 Tbps system, there may need to be around 44 layers in the stack up, such as 10 power layers for high current power and two lower current power layers, as well as 12 high speed routing layers and two miscellaneous layers. The resulting board thickness is around 210 mil.

For a 224 Gbps system, in order to make the signal VIA and ground VIA resonance frequency far away from the Nyquist frequency (which is 56 GHz for 224 PAM4), the ground stitching VIA and signal VIA spacing should no more than 0.6 mm. Ground stitching VIAs are used for XTALK reduction, but these stitching VIAs result in extra voids/openings on the power plane with some implementations resulting in a large quantity of ground VIAs that cut up power planes. Power planes with large cuts introduce micro cavity resonance with negative impact on XTALK, and in addition, the power delivery plane will be impacted because of the large openings creating a DC drop in the plane.

Crosstalk, including both far-end crosstalk (FEXT) and near end crosstalk (NEXT), is difficult to manage since power planes are broken by a large quantity of ground VIAs, which cut up power planes. Power planes with large cut outs introduce micro cavity resonance to the signals. The cavity resonance causes a significant negative impact on crosstalk. One potential solution is to add more power layers, but the resulting challenges are an increased overall board thickness and the aspect ratio for the VIA drills as the VIA structure process (the HDI PCB process) cannot be skipped due to the manufacturing constraints and overall PCB cost.

### BRIEF DESCRIPTION OF THE DRAWINGS

FIG. 1 is a schematic diagram of an example embodiment of a printed circuit board (PCB).

FIG. 2 is a top view of an embodiment of an ASIC of a PCB.

FIG. 3 is a top view of the VIAs for the ASIC illustrated in FIG. 2.

FIG. 4 is a top view of an embodiment of a ground plane of a PCB.

FIG. 5 is a top view of an embodiment of a power plane of a PCB.

FIGS. 6A-6I are various side views of different steps in an exemplary method of manufacturing a PCB, according to the techniques disclosed herein.

FIG. 7A is a perspective view of an example embodiment of a PCB, according to the techniques disclosed herein.

FIG. 7B is a side view of the PCB illustrated in FIG. 7A.

FIG. 7C is a top view of a layer of the PCB illustrated in FIG. 7A.

FIGS. 8A and 8B are screenshots representing a next generation ASIC core power IR drop of a PCB.

FIGS. 9A-9C are screenshots representing a next generation ASIC core power IR drop of a PCB, according to the techniques disclosed herein.

FIGS. 10A-10C are screenshots representing a next generation ASIC core power IR drop of another PCB, according to the techniques disclosed herein.

FIG. 11A is a perspective view of a power plane without additional plating.

FIG. 11B is a close-up perspective view of a portion of the power plane illustrated in FIG. 11A.

FIG. 12A is a perspective view of a power plane with additional plating, according to the techniques disclosed herein.

FIG. 12B is a close-up perspective view of a portion of the power plane illustrated in FIG. 12A.

FIG. 13A is a top view showing the overall DC current density in the power plane illustrated in FIGS. 11A and 11B.

FIG. 13B is a top view showing the overall DC current density in the power plane illustrated in FIGS. 12A and 12B.

### DETAILED DESCRIPTION

### Overview

The problems with related art PCBs are addressed by the techniques disclosed herein with minimum impact to the PCB thickness and cost. The techniques disclosed herein implement unique PCB processes to get more shapes or plane for power delivery without increasing the quantity of layer in the PCB. In some implementations, fewer layers may be a possibility, and/or the overall thickness of the board may be decreased. After a back-drilling process of the plated VIAs, resin is filled into back-drilled VIAs. Another round of plating is applied, and the plating shapes/plane are connected to the power net. For a PTH design, an entire power plane may be located on outer layers. Alternatively, for a one-step HDI design, a power plane may be located on both internal layers (L2 or Ln-1) and outer layers. The terms “power plane” and “power layer” may be used interchangeably herein.

### Example Embodiments

The techniques described herein address power delivery problems for PTH and one-step HDI without any cost added. In some implementations, the cost may decrease if the quantity of layers are reduced. A design and process address power delivery problems for PTH and one-step HDI designs. In some implementations, the quantity of layers may be reduced and the thickness of the board may be reduced. In one embodiment, a PCB is back drilled and a round cap plating is performed to get a more uniform power plane. In one implementation, the back drilled section of a VIA is plated as well, which provides a much bigger shape that is plated for power delivery.

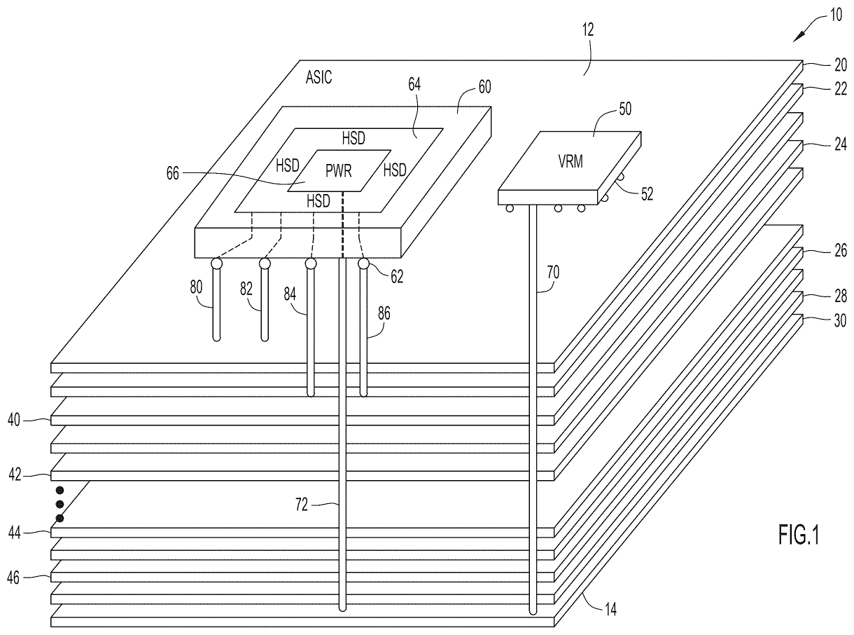

Turning to FIG. 1, a perspective view of a PCB is illustrated. The view in FIG. 1 shows the general power delivery system (VRM to chip load side) on a PCB board. Power VIAs and power layer planes are used for power delivery.

In FIG. 1, an exploded perspective view of an example embodiment of a PCB is illustrated. In this embodiment, PCB 10 has an upper surface 12 and an opposite lower surface 14. The PCB 10 includes a plurality of layers, only some of which are illustrated in FIG. 1. In this embodiment, the PCB 10 includes several high speed routing layers 20, 22, 24, 26, 28, and 30, and several power delivery plane layers 40, 42, 44, and 46.

As shown in FIG. 1, the PCB 10 includes a VRM 50 that is connected to the upper surface 12 of the PCB 10 via connections that are part of a BGA 52. The VRM 50 is connected to the power layers by a power VIA 70 that extends through various layers of the PCB 10. The PCB 10 also includes an ASIC 60 that is connected to the upper surface 12 of the PCB 10 via connections that are part of a BGA 62. The ASIC 60 includes an HSD portion 64 and a power portion 66. The HSD portion 64 is connected to different layers in the PCB 10 by different VIAs 80, 82, 84, and 86, some of which may have different lengths. The power portion 66 of the ASIC 60 is connected to one or more power layers by a power VIA 72.

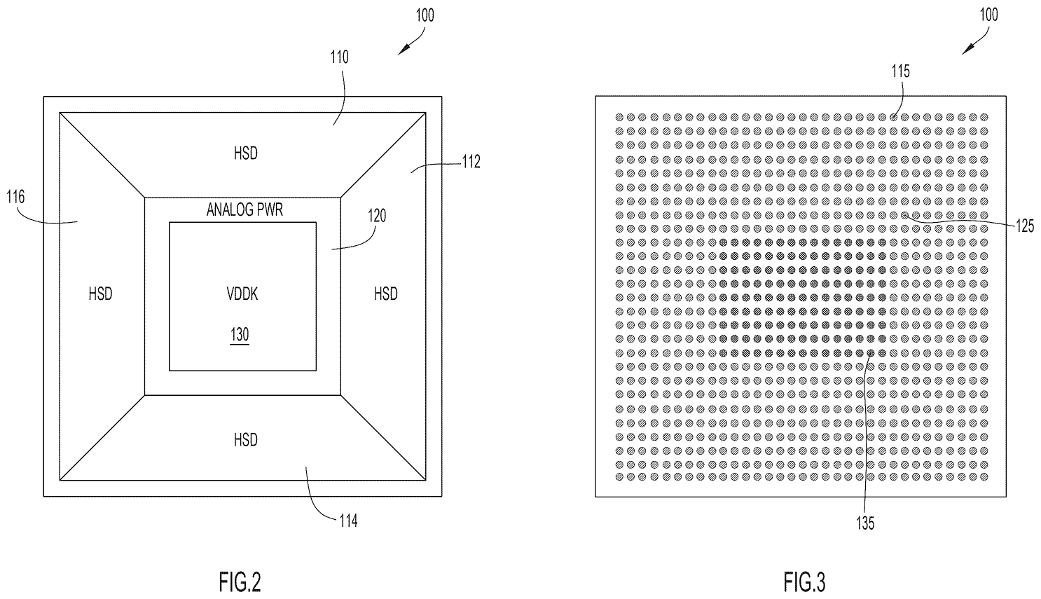

Referring to FIGS. 2 and 3, top views of different aspects of an ASIC of a PCB are illustrated. These top views show a general floor-plan of a next generation switch ASIC. In this ASIC, all high-speed SerDes signals (HSD) are arranged as the outside ring of the BGA and the core power (VDDC) is located at the center of the BGA. The SerDes analog power and other power rails are located between the HSD and the core power area, as described below.

In FIG. 2, the ASIC 100 is a next generation switch ASIC that has several HSD sections or regions 110, 112, 114, and 116 that are located around an analog power region 120. The ASIC 100 also includes a VDDC 130 as well. Turning to FIG. 3, the various VIAs associated with the different regions of the ASIC 100 are illustrated. VIAs 115 are located beneath and are connected to the HSD regions 110, 112, 114, and 116, VIAs 125 are located beneath and are connected to the analog power region 120, and VIAs 135 are located beneath and are connected to the VDDC 130.

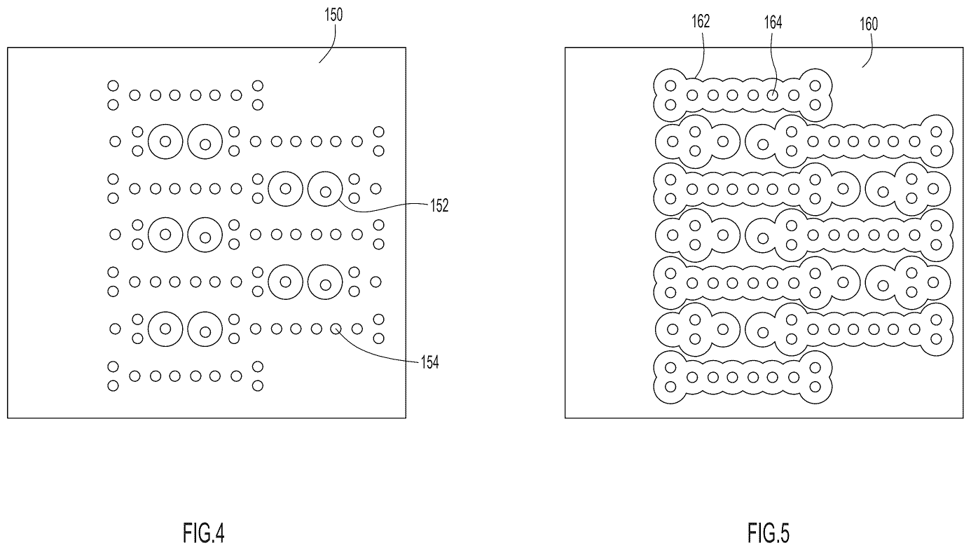

Referring to FIGS. 4 and 5, general ground plane and power planes with the stitching ground VIAs are illustrated. As a 224 Gbps design needs more stitching VIAs to isolation XTALK at the ASIC BGA area, the stitching VIAs cause huge breaks and openings on the power plane, which has a negative impact on power delivery (the DC IR drop is bad).

Turning to FIG. 4, a top view of an embodiment of a ground plane of a PCB is illustrated. In this embodiment, the ground plane 150 includes several cavity structures 152 formed therein. Located around the ground plane 150 are ground stitching VIAs 154. In the cavity structures 152, there are HSD VIAs.

Turning to FIG. 5, a top view of an embodiment of a power plane of a PCB is illustrated. In this embodiment, the power plane 160 has numerous cavities 162 formed therein. As shown in FIG. 5, the cavities 162 interrupt much of the power plane 160 such that any current traveling therethrough will be negatively impacted and affected by the presence of the cavities 162. Located in each of the cavities 162 is a VIA 164.

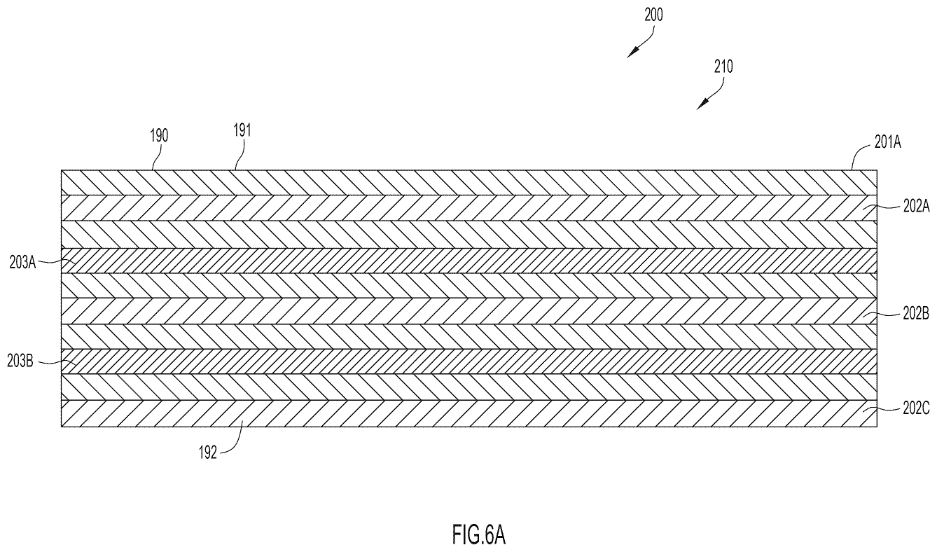

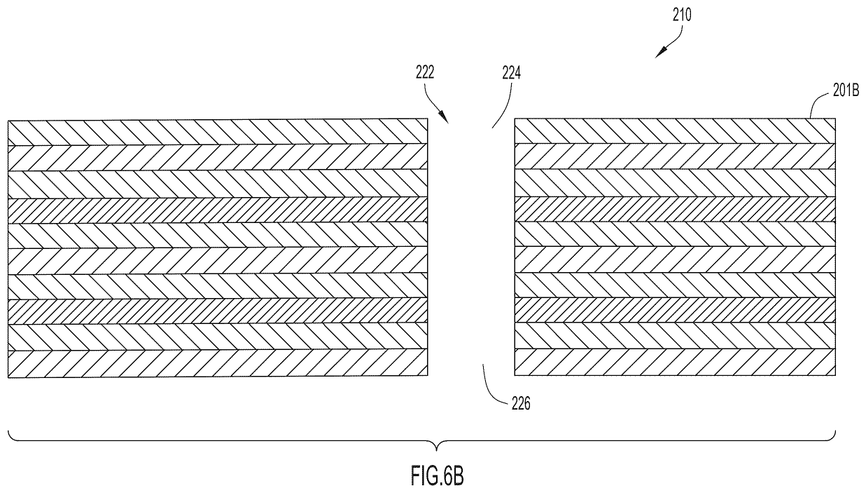

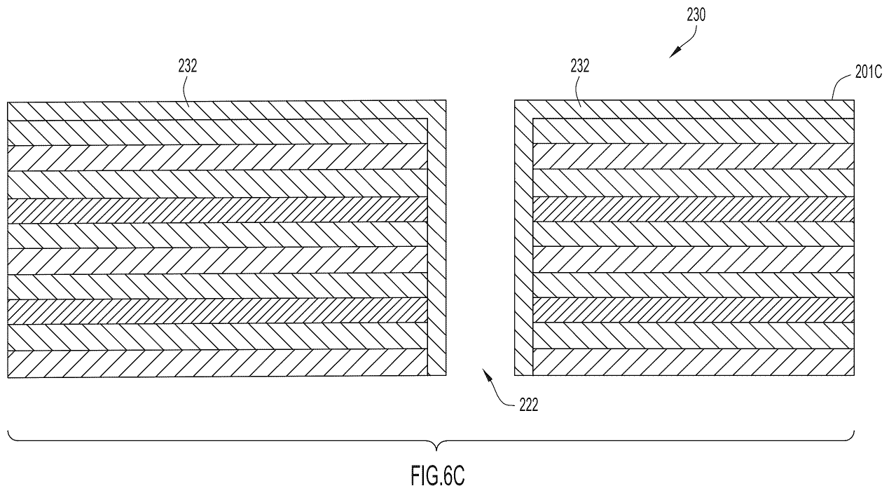

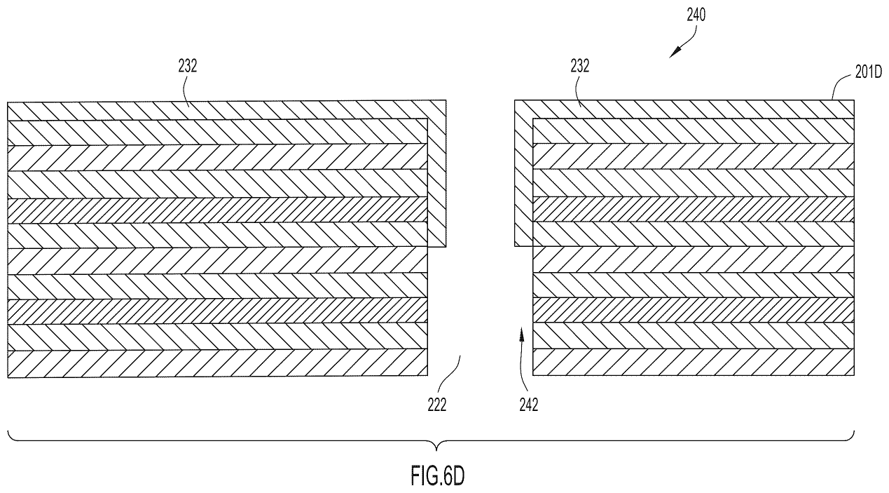

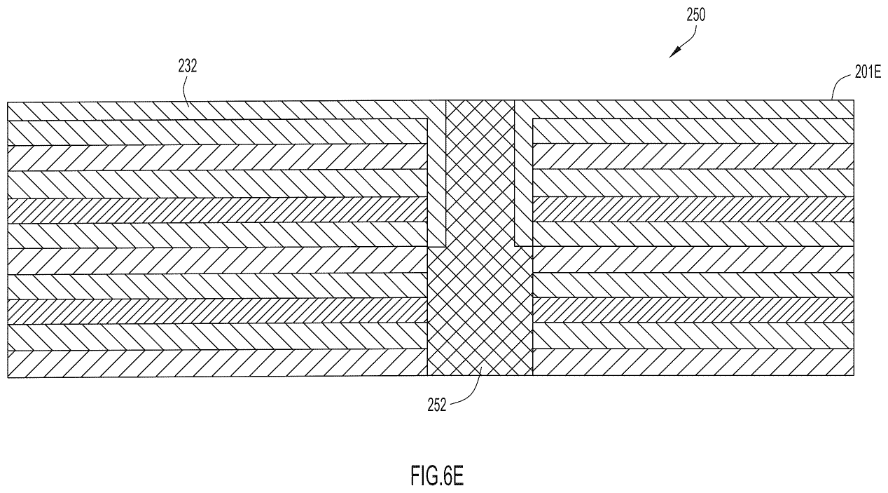

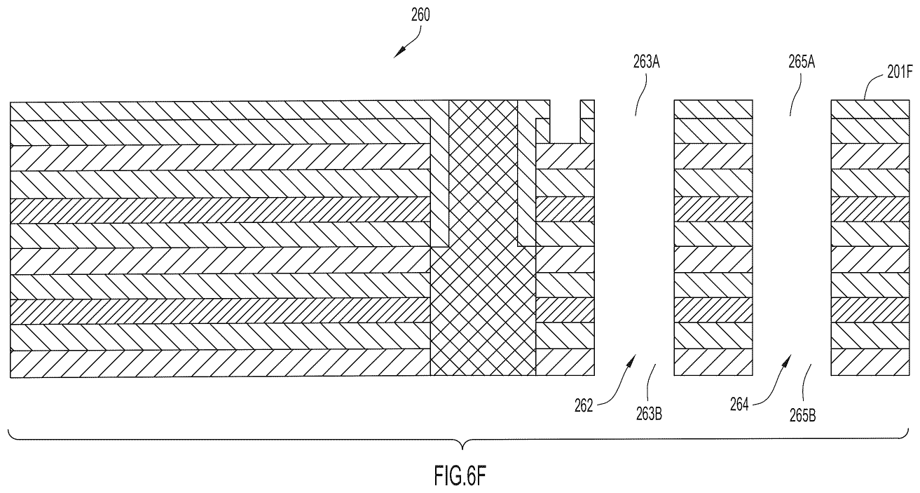

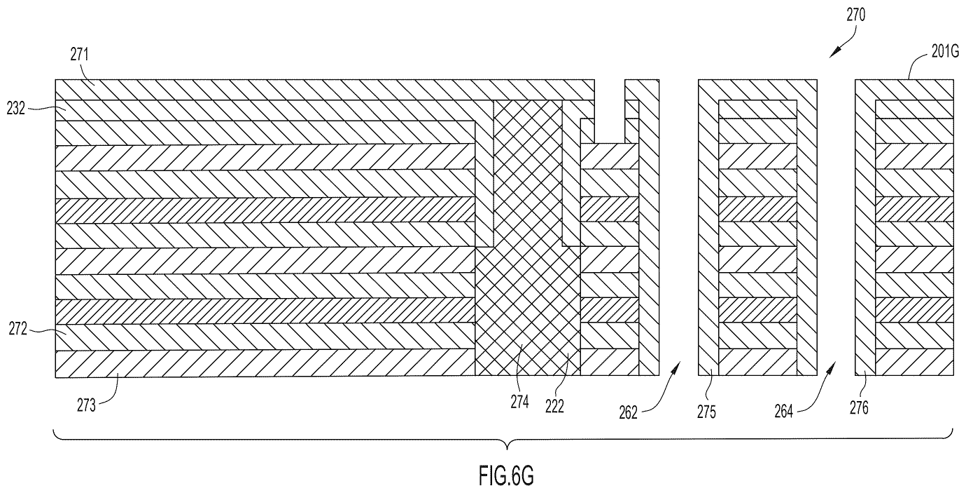

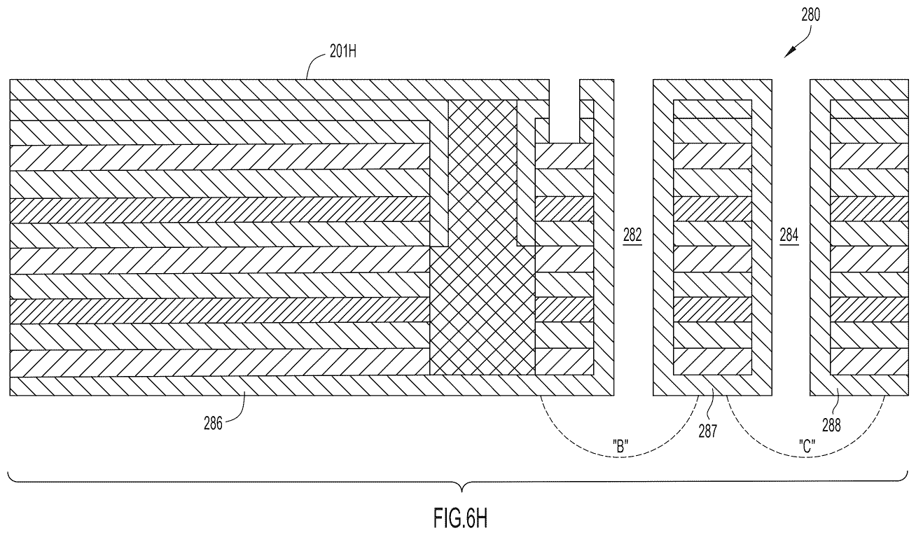

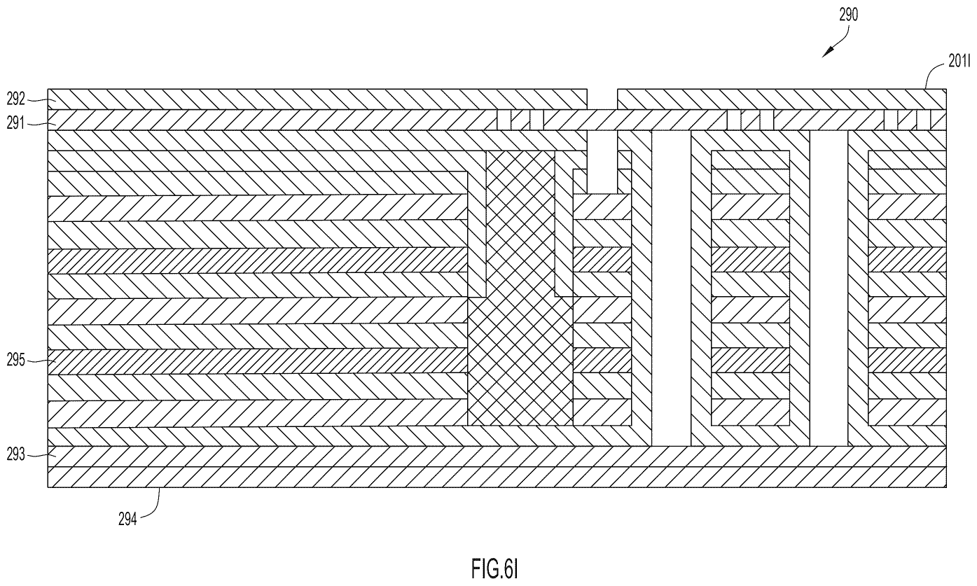

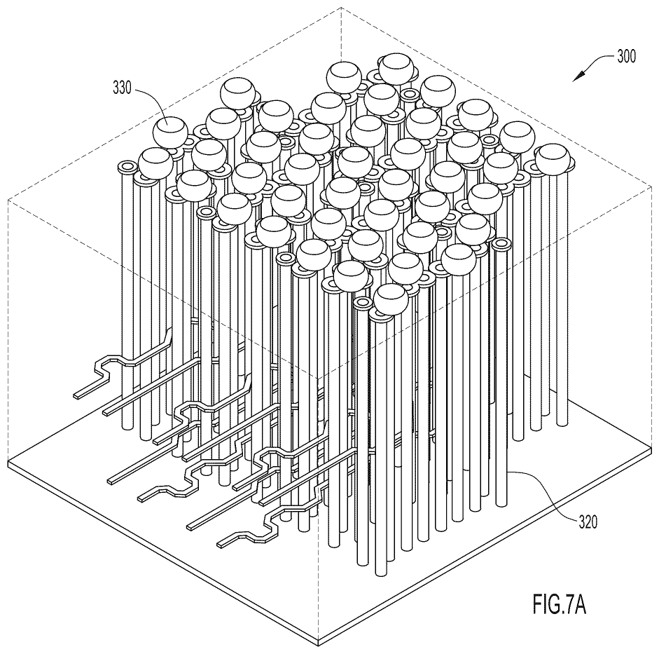

Referring now to FIGS. 6A-6I, various side views of different steps in an exemplary method of manufacturing a PCB, according to the techniques disclosed herein, are illustrated. The exemplary method 200 includes the steps illustrated in FIGS. 6A-6I. The process is for manufacturing a PCB to get plating power shapes. FIGS. 6A-6I can be considered to be a flow chart illustrating an example process for fabricating a printed circuit board according to the disclosed techniques. The process includes the additional plating process for outer layer power shapes/plane. If the process is used for a one-step (1+N+1) HDI process, additional plating can be performed for layers L2, Ln-1, and the bottom layer.

Turning initially to FIG. 6A, step 210 is directed to the formation of the initial body of a PCB. FIG. 6A shows the PCB in an initial configuration 201A. In this configuration, the PCB is a laminated structure 190 that has an upper end 191 and a lower end 192 that is opposite to the upper end 191. In this embodiment, the PCB includes three prepreg layers 202A, 202B, and 202C and two thin core layers 203A and 203B. However, in different embodiments, the PCB may have more or less than three prepreg layers and more than two thin core layers. FIG. 6A shows the layers after the initial lamination process.

Turning to FIG. 6B, step 220 involves drilling to form VIAs. As shown, a VIA 222 is formed when a hole is drilled through all of the layers of the PCB. The VIA 222 includes a first or upper end 224 and a second or lower end 226 that is opposite to the upper end 224. The PCB is illustrated in an intermediate configuration 201B. It is to be understood that more than one VIA 222 can be drilled in the PCB in step 220.

Turning to FIG. 6C, step 230 involves the plating of each drilled VIA. A plating 232 is applied to or plated onto the upper surface of the top layer of the PCB and along the inner surface of the VIA 222 for the full length of the VIA 222. While FIG. 6C appears to illustrate two different platings, it is to be understood that the plating 232 is applied to the upper surface of the top layer, and surrounds the upper opening of the VIA 222. In addition, the plating 232 extends along the inner surfaces of the cylindrical VIA 222. After the plating 232, the PCB has the illustrated intermediate configuration 201C.

Turning to FIG. 6D, step 240 involves back drilling of each VIA. In particular, in this embodiment, VIA 222 is back drilled, which removes a portion of the plating 232 located in the VIA 222. The back drilling results in a back drilled portion 242 where plating 232 has been removed from the inner surface of the VIA 22. After the back drilling, the PCB has the illustrated intermediate configuration 201D.

Turning to FIG. 6E, step 250 involves filling the backfilled VIAs, which results in the PCB being in intermediate configuration 201E. As shown, a filler material 252, such as a resin, is inserted into the back drilled VIA 222. The filler material 252 is inserted into the VIA 222 and fills the VIA 222 from its upper surface defined by the plating 232 to its lower surface defined by the outer surface of the lower of the PCB.

Turning to FIG. 6F, step 260 involves drilling for general plating through holes (PTHs). Intermediate configuration 201F of the PCB includes the PTHs. In this exemplary process, PTH 262 and PTH 264 are drilled through the layers of the PCB separate from the previously described VIA 222. PTH 262 has a first or upper end 263A and a second or lower end 263B opposite to upper end 263A. Similarly, PTH 264 has first or upper end 265A and a second or lower end 265B opposite to upper end 265A.

Turning to FIG. 6G, step 270 involves plating for the general PTHs with VIA cap plating as well. In this step, the PCB has the VIA 222 and the PTHs 262 and 264. A plating layer 271 is added on the upper or outer surface of plating 232. The plating layer 271 surrounds the upper openings of both of the PTHs 262 and 264. In addition, plating layer 271 covers the upper end of the filler material 252 in the VIA 222.

Another prepreg layer 272 and an outer plating layer 273 are located below the lower or outer surface of the lowest layer of the PCB in this intermediate configuration 201G. Layers 272 and 273 have a VIA hole drilled therein that is aligned with VIA 222. Additional filler material or resin 274 is placed into the VIA holes of layers 272 and 273. Also, plating layers 275 and 276 are continuations of plating layer 271, and they extend along the inner surfaces of the PTHs 262 and 264.

Turning to FIG. 6H, step 280 involves additional plating for the outer power shape or plane. In this configuration 201H, the additional plating is an extra layer of plating material that is shown by platings 286, 287, and 288. The result is that PTH 262 is a power VIA 282 and PTH 264 is a power VIA 284. If the power VIAs 282 and 284 are the same net power, they can be connected at the outer layer, as shown by arrows “B” and “C”.

Turning to FIG. 6I, step 290 involves a second lamination for when an HDI process is being performed. In this step, a prepreg layer 291 and an outer plating layer 292 are added to the outside of the upper surface of the uppermost layer of the PCB. In addition, a prepreg layer 293 and an outer plating layer 294 are added to the outside of the lower surface of the lowermost layer of the PCB. In this configuration 201I, a thin core layer 295 instead of layer 272.

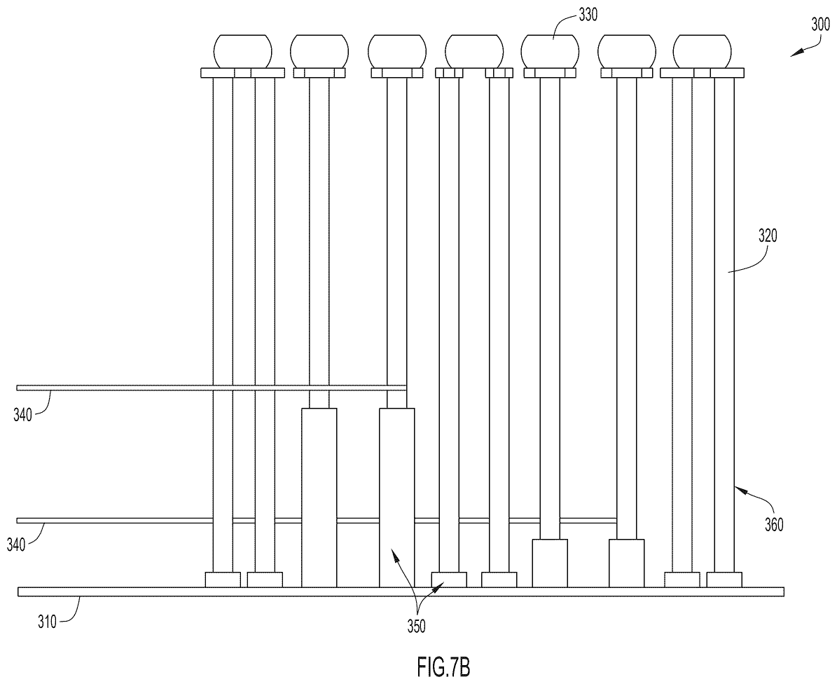

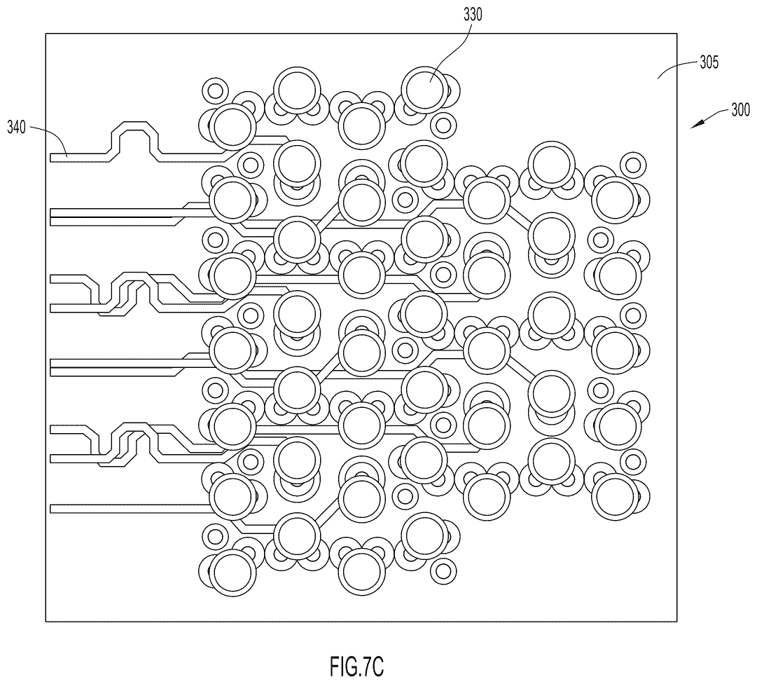

Turning to FIGS. 7A-7C, the BGA area bottom side plating shape according to the techniques disclosed herein is illustrated. In one embodiment, the HSD signal VIAs are back-drilled according the routing layers. All ground VIAs are back-drilled to a target layer that is the deepest layer based on back-drilling tolerance (i.e., 4 mil+3/−2 mil tolerance—the result is the worst stub is 7 mil). Thus, in one implementation, all ground VIAs are back-drilled to a target layer that is 7 mil above the bottom layer in the Z-direction. All back-drilled VIAs (both HSD VIAs and GND VIAs) are resin filled. Afterwards, a final bottom plating is performed for the power shapes/plane. The plating power shape is connected to the BGA side power VIAs and VRM side VIAs.

FIG. 7A is a perspective view of an example embodiment of a PCB, according to the techniques disclosed herein. In FIG. 7A, the PCB 300 includes VIAs 320 and BGA connectors 330. FIG. 7B is a side view of the PCB illustrated in FIG. 7A. In FIG. 7B, the VIAs 320 and BGA connectors 330 are illustrated, along with traces 340. A bottom plating power shape/plane 310 is shown as well as the resin filling 350 that has been inserted into back-drilled VIAs. A ground VIA 360 that has been back drilled and filled with resin is also illustrated. FIG. 7C is a top view of a layer of the PCB illustrated in FIG. 7A. The layer 305 shows multiple traces 340 and BGA connectors 330.

In one aspect of the techniques disclosed herein, for a PTH design, at the ASIC BGA area, assuming the BGA chip is placed on the top layer of the PCB, all HSD areas signals and ground VIAs are back-drilled. HSD signals are back-drilled according to fanout routing layers while ground VIAs are back-drilled to the deepest layer (perhaps Ln-2 or Ln-3) according to back-drill process tolerance (i.e., 4 mil+3/−2 mil tolerance results in the worst stub possibly being 7 mil). Thus, all ground VIAs have a back-drill target layer that is 7 mil above the bottom layer in Z-direction. Resin is then filled into all back-drilled VIAs. Afterwards, a bottom layer plating is applied. The plating shape can be used for core power, SerDes analog power, or any of the power rails of ASIC. In one embodiment, at the front panel cage connector areas, the same process is used to get plating power shapes for a 1.6 Tbps/800 Gbps optics module 3.3 v power rail.

In another aspect of the techniques disclosed herein, for a one-step HDI (L1-L2 micro VIA, L2-Ln-2 PTH and Ln-1-Ln micro VIA) design, at the ASIC BGA area, the same process is used to get power shapes on the Ln-1 layer and the bottom layer. At the front panel belly-to-belly cage connector areas, plating of power shapes for optics modules is provided on L2 layer and Ln-1 layer. In one embodiment, the outer layer copper thickness (foil+plating) is approximately 2 oz. The power shape is much more uniform (due to no openings or voids) as compared to the internal layers. In addition, thermal performance is much better as well. As a result, the power delivery capacity is achieved with much more efficiency.

According IPC guidelines, a 1 mm width 2 oz copper trace current carrying capacity is around 1 Ampere. A next generation ASIC package is around 90 mm×90 mm, so each side can handle around 90 A. Considering a temperature rising derating, some openings and a loss encountered on the path, each side can handle approximately 65 A, and the plating shape can handle as a whole more than 250 A. If the one-step HDI design is followed, there will be an additional plating layer on layer Ln-1. So two additional plating layers can handle around 500 A carrying capacity at the ASIC BGA areas.

The next generation ASIC core power VDDC current is approximately 1120 A. If three internal 2 oz power layers are used for VDDC power delivery, the IR drop is around 12.2%. With this implementation and the additional power plane/shape on the bottom, the IR drop is reduced to 8.1%, which means there is 4% IR drop improvement. Considering the AC requirement and the DC design balance, and keeping more capacitors on the bottom layers, in each direction just one slot is used for power delivery on the bottom, the IR drop is 9.9%, which still has a 2.3% improvement. For a one-step HDI design, the same implementation can be used on layer L2, layer Ln-1 and the bottom layer and the IR drop has a significant improvement.

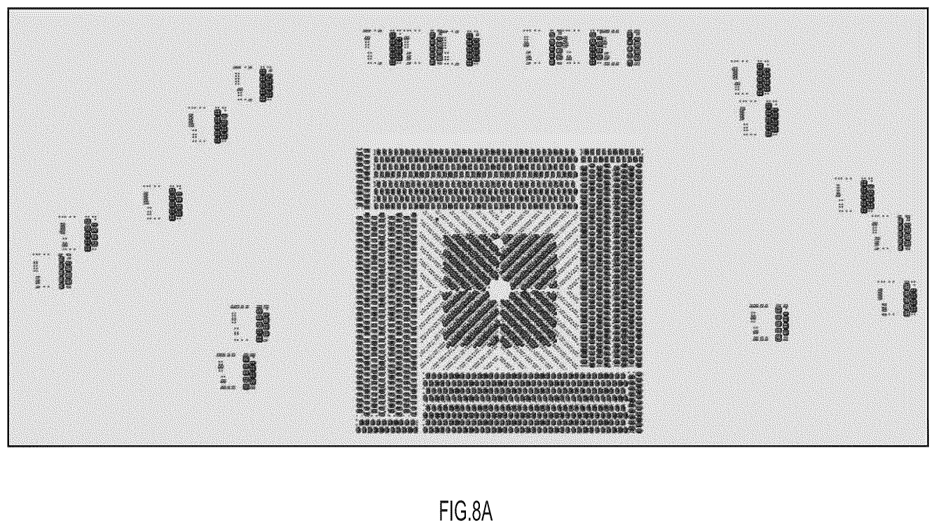

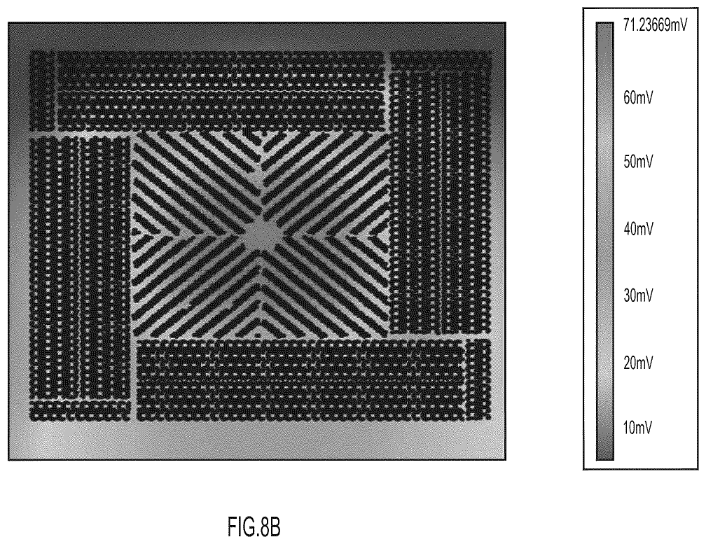

Turning to FIGS. 8A and 8B, screenshots representing a next generation ASIC core power IR drop of a PCB with a general design are illustrated. The details of the measurements shown in FIGS. 8A and 8B are set forth in the following table.

TABLE 1

| | | | | Current | |
|---|---|---|---|---|---|
| | | | Rivers on | Density | |
| PWR | Thickness | Power | Bottom | (A/ | Voltage |
| Planes | (mil) | Bus | Layer | cm\hat{ }2) | Drop (%) |
| P3, P11, P12 | 2.4 | No | N/A | 27,000 | 12.2% |
| Bottom | N/A | No | | | |

With respect to FIGS. 8A and 8B, some of the dimensions and characteristics are: SignalVias_GND via antipad is 25 mil; PowerVias_GND and PowerVias antipad is 27 mil; PowerVias_GND and PowerVias DHS is 10 mil; and the board temperature is 80 degrees Celsius.

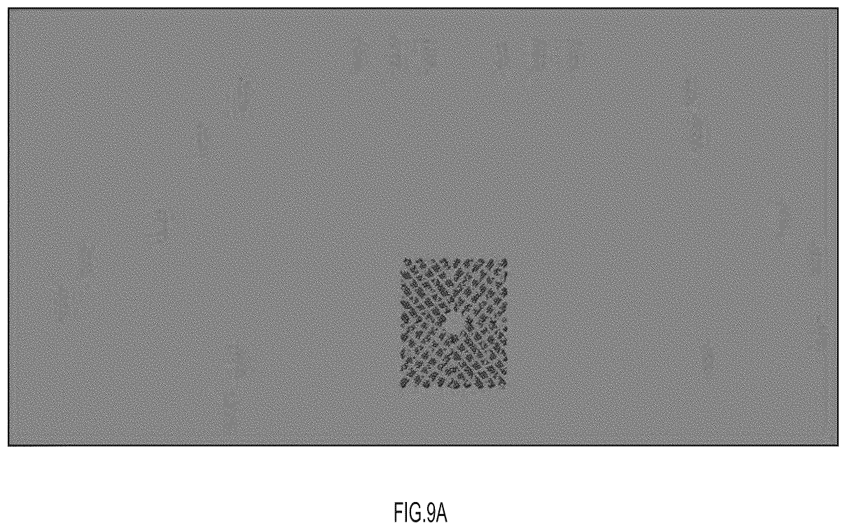

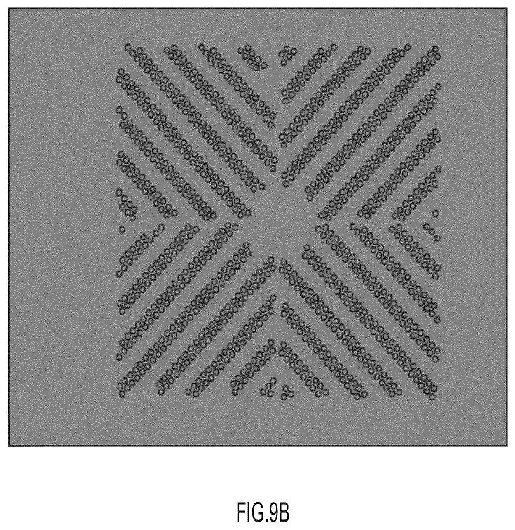

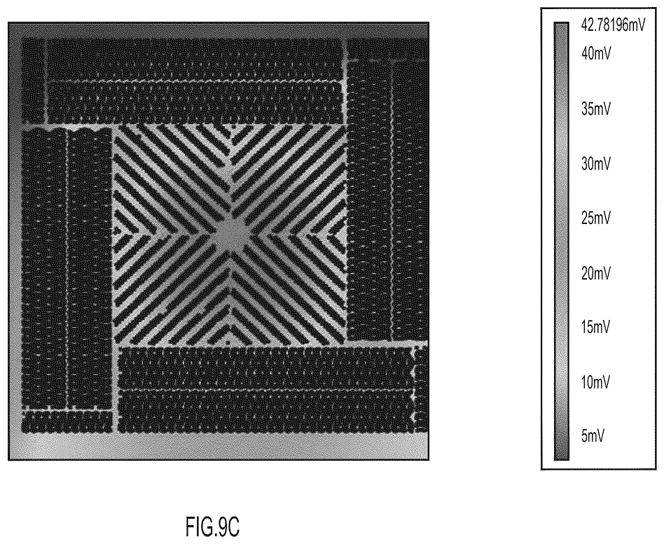

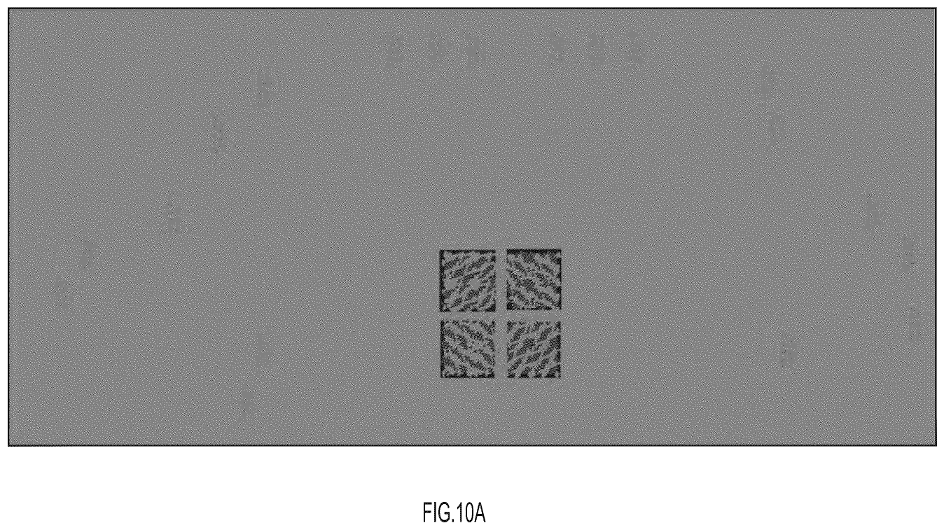

FIGS. 9A-9C are screenshots representing a next generation ASIC core power IR drop of a PCB, according to the techniques disclosed herein. The details of the measurements shown in FIGS. 9A-9C are set forth in the following table.

TABLE 2

| | | | | Current | |
|---|---|---|---|---|---|
| | | | Rivers on | Density | |
| PWR | Thickness | Power | Bottom | (A/ | Voltage |
| Planes | (mil) | Bus | Layer | cm\hat{ }2) | Drop (%) |
| P3, P11, P12 | 2.4 | No | N/A | 21,000 | 8.1% |
| Bottom | 3 | No | | | |

As compared to the contents of Table 1, which relates to FIGS. 8A and 8B, the current density and the voltage drop in Table 2 are both lowered. In particular, the measured current density in FIGS. 9A-9C is 21,000 as compared to a current density of 27,000 in FIGS. 8A and 8B. Also, the measured voltage drop is only 8.1% in FIGS. 9A-9C as compared to a voltage drop of 12.2% in FIGS. 8A and 8B. Thus, the design represented in the screenshots of FIGS. 9A-9C, which has a bottom power plane that is not present in the design represented in FIGS. 8A and 8B, results in an improved current density (a lower current density) and an improved voltage drop (a lower voltage drop).

With respect to FIGS. 9A-9C, some of the dimensions and characteristics are: SignalVias_GND via antipad is 25 mil; PowerVias_GND and PowerVias antipad is 27 mil; PowerVias_GND and PowerVias DHS is 10 mil; PowerVias_GND antipad on Bottom Layer is 28 mil; and the board temperature is 80 degrees Celsius.

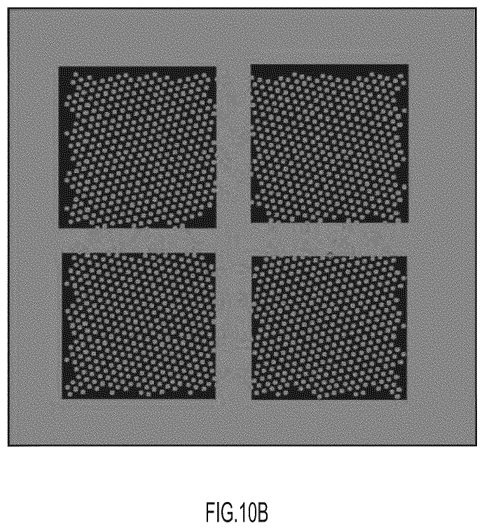

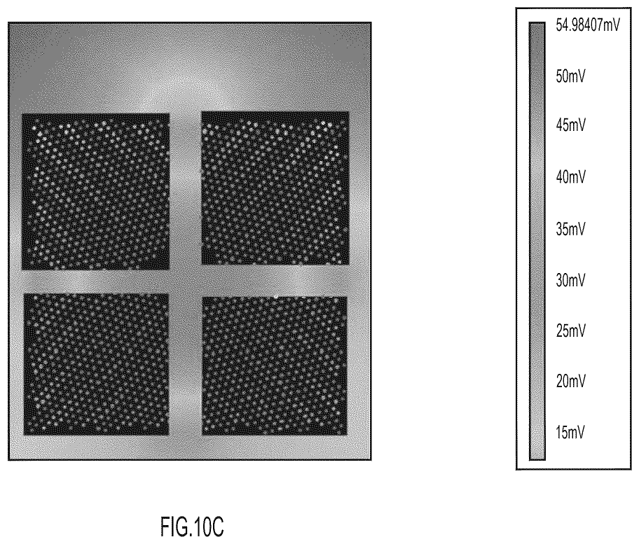

FIGS. 10A-10C are screenshots representing a next generation ASIC core power IR drop of another PCB, according to the techniques disclosed herein. In FIGS. 10A-10C, the drop is shown considering the balance of AC/DC performance and according to the techniques disclosed herein. The details of the measurements shown in FIGS. 10A-10C are set forth in the following table.

TABLE 3

| | | | | Current | |
|---|---|---|---|---|---|
| | | | Rivers on | Density | |
| PWR | Thickness | Power | Bottom | (A/ | Voltage |
| Planes | (mil) | Bus | Layer | cm\hat{ }2) | Drop (%) |
| P3, P11, P12 | 2.4 | No | N/A | 21,000 | 9.9% |
| Bottom | 3 | No | | | |

As compared to the contents of Table 1, which relates to FIGS. 8A and 8B, the current density and the voltage drop in Table 3 are both lowered. In particular, the measured current density in FIGS. 10A-10C is 21,000 as compared to a current density of 27,000 in FIGS. 8A and 8B. Also, the measured voltage drop is only 9.9% in FIGS. 10A-10C as compared to a voltage drop of 12.2% in FIGS. 8A and 8B. Thus, the design represented in FIGS. 10A-10C, which has a bottom power plane that is not present in the design represented in FIGS. 8A and 8B, results in an improved current density (a lower current density) and an improved voltage drop (a lower voltage drop).

With respect to FIGS. 10A-10C, some of the dimensions and characteristics are: SignalVias_GND via antipad is 25 mil; PowerVias_GND and PowerVias antipad is 27 mil; PowerVias_GND and PowerVias DHS is 10 mil; PowerVias_GND antipad on Bottom Layer is 28 mil; and the board temperature is 80 degrees Celsius.

In one embodiment, the front panel cage connector (QDD or OSFP) area can be used the same way for 3.3V optics module power delivery.

In return of this benefit, some internal power layers can be removed, which results in the overall quantity of layers decreasing, and the overall board thickness decreasing. As a result, cost savings are achieved. The techniques described herein are a cost effective solution for 224 Gbps/112 Gbps high density and high power delivery applications.

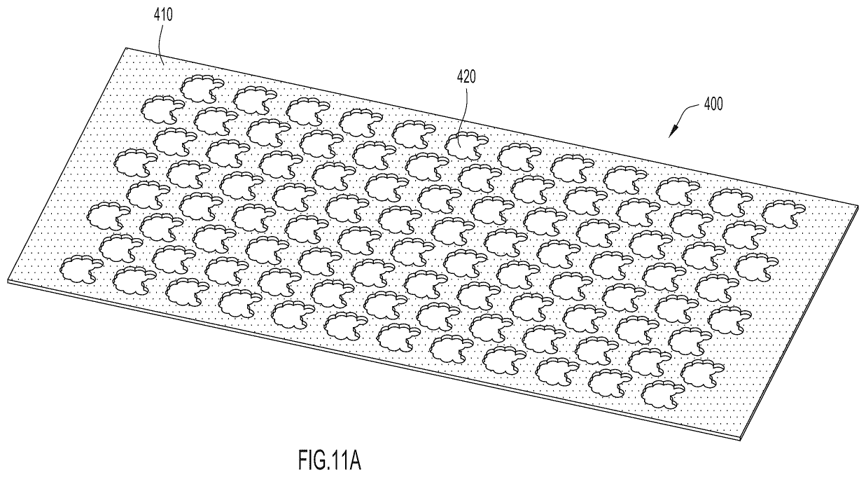

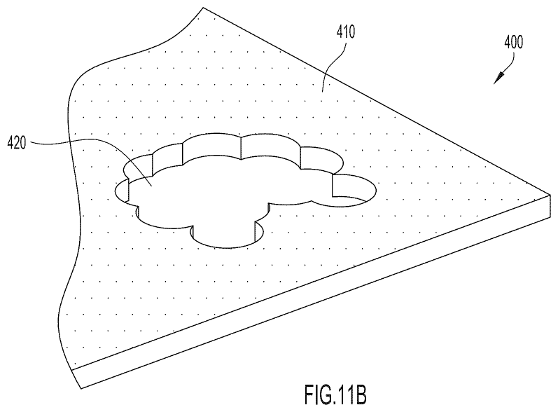

FIG. 11A is a perspective view of a power plane without additional plating, and FIG. 11B is a close-up perspective view of a portion of the power plane illustrated in FIG. 11A. In this embodiment, power plane or power layer 400 includes a body 410 with several openings 420 formed therethrough. The openings 420 are interruptions in the body 410 and adversely affect the flow of current through the body 410 of the power layer 400, thereby reducing the capacity of the power layer 400 to deliver power. In one implementation, the thickness of the power layer 400 is approximately 1 oz.

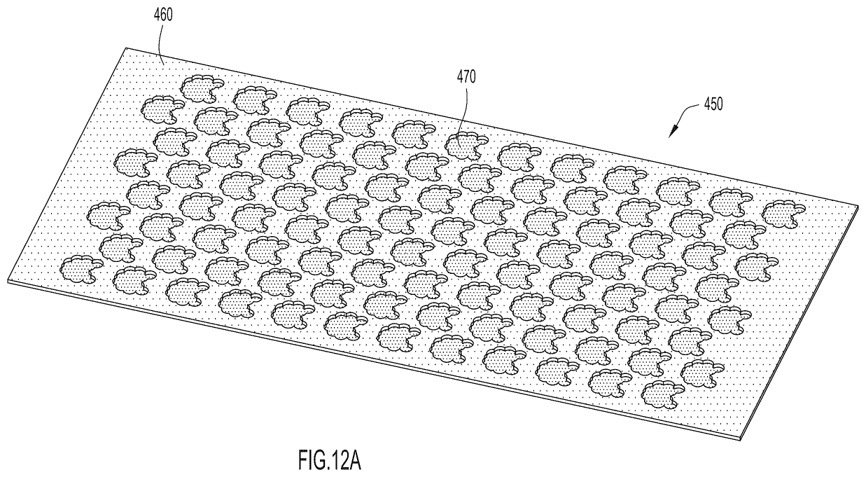

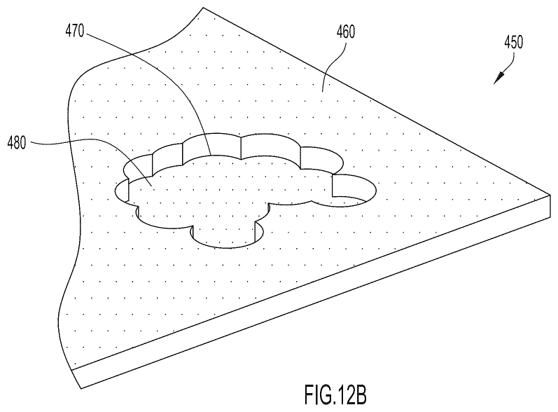

FIG. 12A is a perspective view of a power plane with additional plating, according to the techniques disclosed herein, and FIG. 12B is a close-up perspective view of a portion of the power plane illustrated in FIG. 12A. In this embodiment, power plane or power layer 450 includes a body 460 with several openings 470 formed therein. The openings 470 are shaped and located similarly to openings 420 in power layer 400. However, an additional plating is added to the power layer 400 to form power layer 450. In one implementation, the thickness of the power layer 450 is approximately 2 oz, which results from a 1 oz plating layer being applied to power layer 400. The additional plating layer 480 is applied to the full extent of the lower surface of the power layer. As a result, the additional plating layer 480 can be seen in the openings 470, and prevents the openings 470 from extending fully through the power layer 450. The additional plating layer 480 provides power layer 450 with a continuous body 460 that extends from side to side and end to end. The continuous body of power layer 450 does not have any complete interruptions formed therein, which improves the flow of current through the body 460 of the power layer 450.

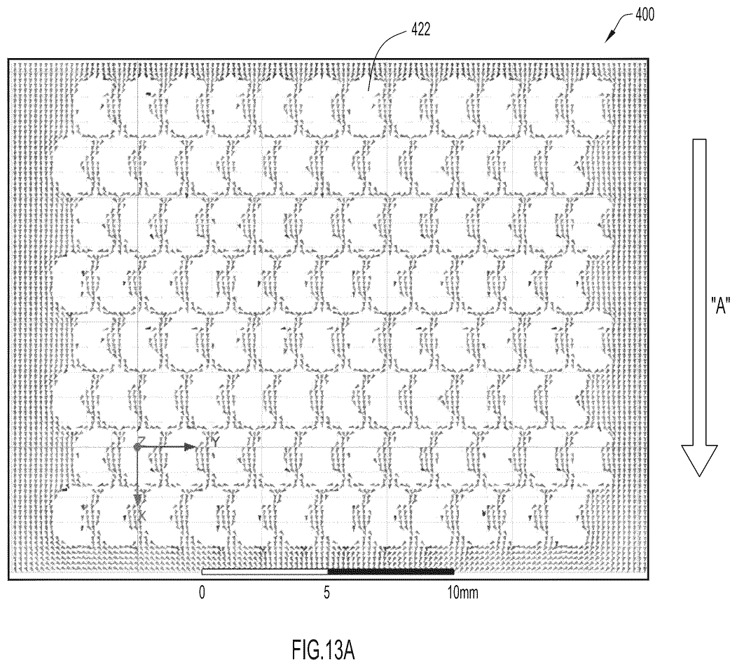

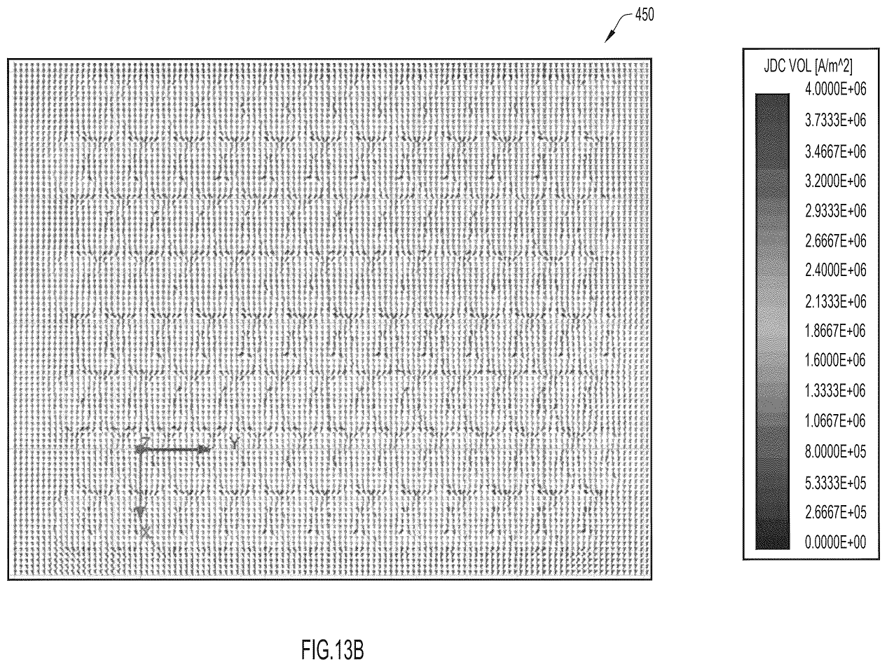

FIG. 13A is a top view showing the overall DC current density in power layer 400, which was illustrated in FIGS. 11A and 11B and described above. The current is flowing along the direction of arrow “A.” There are open spaces 422 in the current flow across power layer 400, which are the direct result of openings 420 in body 410 of power layer 400. Not only are the openings 420 forming gaps or open spaces 422 in the current flow, but they are also forcing the current to flow through narrow portions of the body 410 located between the openings 420. By forcing current through the narrow portions around the openings 420, the thermal performance of the power layer 400 is decreased. The majority of the measurements of the DC current density in power layer 400 in FIG. 13A, which are shown in units of A/m², are the range of 2.6667E+06 A/m² to 1.0667E+06 A/m² shown in the key adjacent to FIG. 13B.

FIG. 13B is a top view showing the overall DC current density in power layer 450, which is illustrated in FIGS. 12A and 12B and described above. The current is also flowing along the direction of arrow “A.” Notable is the current flowing through the entire body 460 of power layer 450. While the openings 470 still exist in body 460, the additional plating material allows current to flow therethrough beneath the openings 470. The result is a more uniform current flow through power layer 450 as compared to power layer 400 because of the additional plating material added to power layer 450. The more uniform current flow results in a better overall thermal performance (not an increased temperature) of the power layer 450. The majority of the measurements of the DC current density in power layer 450 in FIG. 13B, which are shown in units of A/m², are the range of 1.0667E+06 A/m² to 2.6667E+05 A/m² shown in the key. Thus, the additional plating reduces the overall DC current density, as seen by comparing power layer 450 to power layer 400.

In summary, there are several advantages of the example embodiments of circuit boards and processes according to the disclosed techniques. The power delivery system design described herein has benefits with PCB manufacturing processes.

One benefit is excellent power delivery both at the BGA area and the front panel connector (QDD or OSFP) areas for a next generation high density signaling and high power delivery system. The system provides improved power delivery and reduces DC drop by reducing openings/cut-outs formed in power plane/shapes.

Another benefit is more power planes on outer layers or internal layers, which can reduce the total layer count and the overall board thickness. The result is a low cost PCB with good PI performance for a 224G high density system.

Another benefit is thermal performance is improved with more power shapes on board and long-term reliability is improved as well.

Another benefit is that a back-drilling process with an additional lamination process is used. An outer layer is generated (and internal layers L2/Ln-1 for one-step HDI) and a plating Gerber file is ok, thereby not requiring additional effort for an eCAD engineer and the same DFM/DFA rules may be kept.

Another benefit is resin filling for back-drilled VIAs and no CAF issues (no glass-weave with VIA after resin filling).

With the design and process according to the techniques disclosed herein, excellent SI/PI performance, improvements in the long-term manufacturing reliability, and overall cost savings are achieved.

In some aspects, the techniques described herein relate to a printed circuit board, comprising: a laminated structure having an upper end and a lower end opposite to the lower end, the laminated structure including prepreg layers; thin core layers; a via that is back-drilled and filled with a resinous material; a through hole extending from the upper end to the lower end, the through hole being plated; and a first plating on the lower end of the laminated structure, wherein the first plating covers a lower end of the via and is an outer power layer.

In some aspects, the techniques described herein relate to a second plating on the upper end of the laminated structure, the second plating covering an upper end of the via.

In some aspects, the techniques described herein relate to the through hole being a first through hole, and the laminated structure further comprises: a second through hole extending from the upper end to the lower end, and the second through hole being plated.

In some aspects, the techniques described herein relate to the first through hole being a first power via, the second through hole is a second power via, and the first through hole is connected to the second through hole by the first plating.

In some aspects, the techniques described herein relate to the laminated structure including an additional prepreg layer laminated thereon, the additional prepreg layer covers a lower end of each of the first through hole and the second through hole.

In some aspects, the techniques described herein relate to the laminated structure including a full outer layer plating applied to the additional prepreg layer.

In some aspects, the techniques described herein relate to a printed circuit board, comprising: a plurality of layers including prepreg layers and thin core layers, the plurality of layers having an upper end and a lower end; a via that is formed in the plurality of layers and back-drilled, the via being filled with a resinous material, the via having a first end and a second end opposite to the first end; a through hole formed in the plurality of layers, the through hole extending from the upper end to the lower end, the through hole being plated; a first outer plating on the upper end of the plurality of layers, the first outer plating covering the first end of the via; and a second outer plating on the lower end of the plurality of layers, and the second outer plating covering the second end of the via, wherein the second outer plating is an outer power layer.

In some aspects, the techniques described herein relate to the through hole being a first through hole, and the printed circuit board further comprises: a second through hole extending from the upper end to the lower end, and the second through hole is plated.

In some aspects, the techniques described herein relate to the first through hole being a first power via, the second through hole is a second power via, and the first through hole is connected to the second through hole by the second outer plating.

In some aspects, the techniques described herein relate to the plurality of layers being laminated together, and the printed circuit board further comprises: an additional prepreg layer laminated thereon, the additional prepreg layer covering a lower end of the first through hole and a lower end of the second through hole.

In some aspects, the techniques described herein relate to the second outer plating covering the additional prepreg layer.

In some aspects, the techniques described herein relate to a method of manufacturing a printed circuit board (PCB), comprising the steps of: selecting a plurality of layers; laminating the plurality of layers to form a laminated structure; forming a via through the laminated structure; plating an upper surface of the laminated structure and an inner surface of the via; back-drilling the via; filling the via with a material; and plating a lower surface of the laminated structure to form an outer power plane.

In some aspects, the techniques described herein relate to the plurality of layers including multiple prepreg layers and multiple thin core layers.

In some aspects, the techniques described herein relate to the method further comprising the steps of: after the step of back-drilling the via, drilling at least one hole through the laminated structure spaced apart from the via; and plating the at least one hole.

In some aspects, the techniques described herein relate to the step of plating the at least one hole includes plating an upper end of the via that is filled.

In some aspects, the techniques described herein relate to method further comprising: the step of adding another prepreg layer to the laminated structure.

In some aspects, the techniques described herein relate to the step of plating a lower surface of the laminated structure to form an outer power plane includes plating a lower end of the via.

In some aspects, the techniques described herein relate to the step of plating a lower surface of the laminated structure to form an outer power plane includes plating a lower surface of the laminated structure proximate to the at least one hole.

In some aspects, the techniques described herein relate to the at least one hole being a power via for the PCB.

In some aspects, the techniques described herein relate to the step of plating a lower surface of the laminated structure including plating an entire lower surface of the laminated structure to form a continuous power plane.

### Variations and Implementations

Note that in this specification, references to various features (e.g., elements, structures, nodes, modules, components, engines, logic, steps, operations, functions, characteristics, etc.) included in “one embodiment,” “example embodiment,” “an embodiment,” “another embodiment,” “certain embodiments,” “some embodiments,” “various embodiments,” “other embodiments,” “alternative embodiment,” and the like are intended to mean that any such features are included in one or more embodiments of the present disclosure, but may or may not necessarily be combined in the same embodiments.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase “at least one of,” “one or more of,” “and/or,” variations thereof, or the like are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms “first,” “second,” “third,” etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A printed circuit board, comprising:
a laminated structure having an upper end and a lower end opposite to the lower end, the laminated structure including:
prepreg layers;
thin core layers;
a via that is back-drilled and filled with a resinous material;
a through hole extending from the upper end to the lower end, the through hole being plated; and
a first plating on the lower end of the laminated structure, wherein the first plating covers a lower end of the via and is an outer power layer.

2. The printed circuit board of claim 1, comprising a second plating on the upper end of the laminated structure, the second plating covering an upper end of the via.

3. The printed circuit board of claim 1, wherein the through hole is a first through hole, and the laminated structure further comprises:
a second through hole extending from the upper end to the lower end, and the second through hole being plated.

4. The printed circuit board of claim 3, wherein the first through hole is a first power via, the second through hole is a second power via, and the first through hole is connected to the second through hole by the first plating.

5. The printed circuit board of claim 4, wherein the laminated structure includes an additional prepreg layer laminated thereon, the additional prepreg layer covers a lower end of each of the first through hole and the second through hole.

6. The printed circuit board of claim 5, wherein the laminated structure includes a full outer layer plating applied to the additional prepreg layer.

7. A printed circuit board, comprising:
a plurality of layers including prepreg layers and thin core layers, the plurality of layers having an upper end and a lower end;
a via that is formed in the plurality of layers and back-drilled, the via being filled with a resinous material, the via having a first end and a second end opposite to the first end;
a through hole formed in the plurality of layers, the through hole extending from the upper end to the lower end, the through hole being plated;
a first outer plating on the upper end of the plurality of layers, the first outer plating covering the first end of the via; and
a second outer plating on the lower end of the plurality of layers, and the second outer plating covering the second end of the via, wherein the second outer plating is an outer power layer.

8. The printed circuit board of claim 7, wherein the through hole is a first through hole, and the printed circuit board further comprises:
a second through hole extending from the upper end to the lower end, and the second through hole is plated.

9. The printed circuit board of claim 8, wherein the first through hole is a first power via, the second through hole is a second power via, and the first through hole is connected to the second through hole by the second outer plating.

10. The printed circuit board of claim 8, wherein the plurality of layers are laminated together, and the printed circuit board further comprises:
an additional prepreg layer laminated thereon, the additional prepreg layer covering a lower end of the first through hole and a lower end of the second through hole.

11. The printed circuit board of claim 10, wherein the second outer plating covers the additional prepreg layer.

12. A method of manufacturing a printed circuit board (PCB), comprising steps of:
selecting a plurality of layers;
laminating the plurality of layers to form a laminated structure;
forming a via through the laminated structure;
plating an upper surface of the laminated structure and an inner surface of the via;
back-drilling the via;
filling the via with a material; and
plating a lower surface of the laminated structure to form an outer power plane.

13. The method of claim 12, wherein the plurality of layers includes multiple prepreg layers and multiple thin core layers.

14. The method of claim 12, wherein the method further comprises:
after the step of back-drilling the via, drilling at least one hole through the laminated structure spaced apart from the via; and
plating the at least one hole.

15. The method of claim 14, wherein plating the at least one hole includes plating an upper end of the via that is filled.

16. The method of claim 15, further comprising:
adding another prepreg layer to the laminated structure.

17. The method of claim 16, wherein plating a lower surface of the laminated structure to form an outer power plane includes plating a lower end of the via.

18. The method of claim 17, wherein plating a lower surface of the laminated structure to form an outer power plane includes plating a lower surface of the laminated structure proximate to the at least one hole.

19. The method of claim 14, wherein the at least one hole is a power via for the PCB.

20. The method of claim 12, wherein plating a lower surface of the laminated structure includes plating an entire lower surface of the laminated structure to form a continuous power plane.
